(19) United States
(12) Patent Application Publication
(10) Pub. No.: US 2003/0027419 A1
(43) Pub. Date: Feb. 6, 2003

(54) Tri-tone photomask to form dual damascene structures

(75) Inventor: Zheng G. Chen, Beacon, NY (US)

Correspondence Address: Todd M. C. Li, Internaional Business Machines Corporation, 2070 Route 52, Zip 482, Hopewell Junction,, NY, 12533, US

(73) Assignee: INTERNATIONAL BUSINESS MACHINES CORPORATION, ARMONK, NY

(21) Appl. No.: 09/921,257

(22) Filed: Aug. 2, 2001

(51) Int. Cl. H01L 21/4763

(52) U.S. Cl. 438/638; 438/618

(57) ABSTRACT

A method for forming interconnect dual damascene structures comprising: first, performing a low-k dielectric spin-on; wherein the low-k dielectric is photosensitive and is copper; second, forming trench and vias in the low-k dielectric with a tri-tone mask; and third, applying a liner deposition in the trench and vias; wherein the tri-tone mask comprises a plurality of transmissions, wherein the transmissions of the tri-tone mask is in the range of 0% to 100%. The transmission of the tri-tone mask further comprises a transmission of 0% corresponding to non-erosion regions of the dielectric. Moreover, the transmission of the tri-tone mask further comprises a transmission of 100% corresponding to via regions of the dielectric. Furthermore, the range of 0% to 100% corresponds to trench regions of the dielectric.

### BACKGROUND OF THE INVENTION

1. Field of the Invention

The present invention generally relates to an ultra large scale integrated (ULSI) circuit multilevel interconnect fabrication process, and more particularly to an improved method for forming interconnect dual damascene structures.

2. Description of the Related Art

A semiconductor chip usually contains devices and interconnects. The process to make devices is usually called Front End Of Line (FEOL) and the process to make interconnects is usually called Back End Of Line (BEOL). Moreover, on-chip interconnects are the way to make electrical connections between the functional blocks of a system.

On-chip interconnects are now one of the most challenging areas of integrated circuit processing. Previously, the greatest challenges to processing involved forming the active device elements. Interconnects, composed primarily of aluminum and silicon dioxide, were relatively simple and had clear evolution paths for development. However, a radical shift in importance has occurred because chip speeds are now in the gigahertz and beyond range, and each signal sent across the chip has barely enough time to reach the other side before the next signal is sent. This signal delay is proportional to the product of the dielectric's capacitance and the conductor's resistance. Summarily, high speed logic designs must now take into account this “RC delay”. In order to yield higher chip speeds, the materials used to construct these interconnects can by changed. For instance, by changing from aluminum to copper reduces the resistance by approximately 40%, and by changing from silicon dioxide to a relatively ideal low-k dielectric reduces the capacitance by approximately 50%. Combined, these two changes should allow chips to operate approximately four times faster than conventional chips. However, radically new structures, designs and processes will be needed to enter this so-called “gigahertz era”.

Copper metalization has been previously introduced for the 0.22 μm technology node in order to lower the resistance and provide a higher performance wiring technology. At the 0.13 μm technology node, the semiconductor industry will implement copper and low-k dielectric insulators for CMOS BEOL. Various low-k materials have been demonstrated but low-k implementation has proven difficult with copper due to mechanical and chemical issues. The semiconductor industry has focused primarily on spin-on organic materials and PECVD (plasma chemical vapor deposition) carbon-doped silicon dioxide derivatives for low-k integration options. The integration process employed dictates the requirements that low-k dielectric materials must meet. Moreover, fundamental material and process requirements must be met. In light of this, one of the process challenges is etch selectivity, whereby the organic dielectric behaves like a photoresist during the plasma etching process. This new dielectric and integration scheme has driven the development of selective etch recipes and unique post-etch cleans. However, one important concern is that the etch must accept profiles without bowing and micro trenching.

As mentioned, currently both copper metallurgy and low dielectric constant (k) materials are used to improve integrated circuit interconnection performance. The method of forming interconnects likely occurs using dual damascene (DD) processing. An example of a conventional and complete interconnect DD processes comprises: (a) photolithography to define line patterns into photoresist; b) etch to transfer the resist pattern into dielectric to form trench; (c) photolithography to define via patterns into photoresist, (d) etch to transfer the resist patterns into dielectric to form via; and (e) liner deposition and metal fill. The exact process sequence may vary, depending on line-first or via-first flow.

Examples of conventional processes are described in various U.S. Patents, the complete disclosures thereof are incorporated herein by reference. For example, U.S. Pat. No. 6,180,512 and U.S. Pat. No. 5,976,968 describe a single mask dual damascene, whereby the above-identified steps (a) and (c) are combined into one step using optical lithography. However, all of the other steps are still used to form interconnect dual damascene structures.

Similarly, U.S. Pat. No. 6,174,801 B1 describes e-beam direct writing, whereby the above-identified steps (a) and (c) are combined into one step by using e-beam writing. However, all of the other steps are still used to form interconnect dual damascene structures. Likewise, U.S. Pat. No. 5,914,202 and U.S. Pat. No. 5,936,707 each describe a multilevel reticle system for forming multilevel resist profiles, where the above-identified steps (a) and (c) are combined into one step. They are similar to U.S. Pat. No. 6,180,512 and U.S. Pat. No. 5,976,968, wherein additional etch steps are also needed in order to form interconnect dual damascene structures. Other conventional systems describe a method of manufacturing a mask with a plurality of transmissive levels. However, this is just a sub-step to realize the combination of the above-identified steps (a) and (c).

Usually, an interconnect system contains one or more layers of metal wiring that are separated from each other by an insulating dielectric layer(s). Conducting the layers of metals is achieved by a via. FIG. 1 shows a schematic cross-sectional drawing of a hierarchical interconnect architecture, where M# represents wiring and V# represents a via. Typically, an interconnect contains anywhere from three to ten levels of hierarchical wiring, which are built layer by layer with a process called a dual damascene process.

FIGS. 2(a) through 2(f) show a conventional dual damascene integration scheme. Here, the processes include photolithography to define line and via patterns separately into photoresists, etching to transfer the resist patterns to low-k dielectrics and a liner deposition/metal fill. Specifically, as shown, first and second hard mask layers 205, 210 are applied on a low-k dielectric 200 (FIG. 2(a)). Then, a photoresist is applied 215. After which, the photoresist is exposed with a wiring mask, and the second hard mask layer 210 is etched, thereby leaving a trench 220 (FIG. 2(b)). Next, the wiring level resist is stripped, and a via resist is applied 250. Then, the resist is exposed with a via mask, and the first hard mask layer 205 is etched, thereby leaving a via hole 225 in hard mask 205 (FIG. 2(c)). The next step involves partially etching the via resulting in a deeper via hole 230 (FIG. 2 (d)). Upon which the first hard mask layer 205 is opened 235 for a wire etch, thereby allowing for a wire 230 and via 235 etch (FIG. 2(e)). Finally, a liner deposition and Cu electroplating are performed with a metal fill 240 (FIG. 2 (f)). Additionally, the plasma etching of a low-k organic material and resist strip steps are among the most critical for the integration of low-k dielectric due to low selectivity to resist. As shown, this conventional process is complicated and rather expensive. Thus, there is a need for an improvement to the conventional method, which simplifies the process and overcomes the etching problems.

### SUMMARY OF THE INVENTION

In view of the foregoing and other problems, disadvantages, and drawbacks of the conventional integration of multilevel interconnect ULSI fabrication, the present invention has been devised, and it is an object of the present invention to provide a method for a simplified process flow to form interconnect dual damascene structures.

It is a further object of the invention to simplify the dual damascene process by combining the above-identified processing steps (a), (b), (c), (d) and (e) into only one lithographic step in order to form interconnect dual damascene structures.

It is yet another object of the present invention to provide a new simplified dual damascene process, which reduces ULSI fabrication costs.

It is still another object of the present invention to provide a new process to solve the interconnect dual damascene integration challenge using a new concept of photosensitive low-k material and tri-tone mask photolithography.

In order to attain the objects suggested above, there is provided, according to one aspect of the invention a method for forming interconnect dual damascene structures comprising minimal steps. The first step is to perform a low-k dielectric spin-on; wherein the low-k dielectric is photosensitive (i.e., the dielectric is a photoresist). The second step is to form a trench and via in the low-k dielectric with a tri-tone mask. The third and final step is to apply a liner deposition and metal fill in the trench and vias. The tri-tone mask comprises a plurality of transmissions, wherein the transmissions of the tri-tone mask is in the range of 0% to 100%. The transmission of the tri-tone mask further comprises a transmission of 0% corresponding to non-erosion regions of the dielectric. Moreover, the transmission of the tri-tone mask further comprises a transmission of 100% corresponding to via regions of the dielectric. Furthermore, the range of 0% to 100% corresponds to trench regions of the dielectric.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a cross-sectional view of a conventional hierarchical interconnect architecture;

FIG. 2(a) is a cross-sectional view of a conventional dual damascene integration scheme;

FIG. 2(b) is a cross-sectional view of a conventional dual damascene integration scheme;

FIG. 2(c) is a cross-sectional view of a conventional dual damascene integration scheme;

FIG. 2(d) is a cross-sectional view of a conventional dual damascene integration scheme;

FIG. 2(e) is a cross-sectional view of a conventional dual damascene integration scheme;

FIG. 2(f) is a cross-sectional view of a conventional dual damascene integration scheme;

FIG. 3(a) is a cross-sectional view of a dual damascene integration scheme according to the present invention;

FIG. 3(b) is a cross-sectional view of a dual damascene integration scheme according to the present invention; and

FIG. 4 is a flow diagram illustrating a preferred method of the invention.

### DETAILED DESCRIPTION OF PREFERRED EMBODIMENTS OF THE INVENTION

As mentioned above, because dual damascene processing is likely to be the way interconnects are formed, there is a need for an improved dual damascene integration process. As generally known to those skilled in the art, low-k dielectrics are applied in ULSI BEOL processing to improve interconnect performance. Conventional dual damascene processes include photolithography to define line and via patterns separately into photoresists, and etching to transfer the resist patterns to low-k dielectrics. To simplify these procedures, it is possible to make a low-k material photosensitive and then to use photolithography only to define patterns directly into low-k dielectrics, since most of the low-k dielectric candidates are organic spin-on materials like photoresists. With this idea, the dual damascene process sequences are low-k spin-on, line and via photos (to form trenches and vias in the photosensitive low-k) and a metal fill. The photoresist may also be stripped to form a super low-k dielectric with k=1 (air), such that the process comprises the super low-k interconnects or strip resists and then a recoating, any needed, of the low-k dielectrics. The main advantage is to simplify the dual damascene process by ignoring the reactive ion etching (RIE) step.

One of the problems solved by the present invention is the ability to form dual damascene structures in photosensitive low-k dielectrics. Basically, different photon intensities need to deliver into the photoresist to form the staircase profiles since the photoresist dissolution rate is a function of the absorbed number of photons. Conventionally, a photoresist (also shown as a dielectric here) is exposed twice by a line level mask and a via level mask, or the photoresist is exposed by an electron beam (e-beam) with different intensities at via/line locations to form a staircase dual damascene profile. One of the novel aspects of the present invention is the ability to build an optical mask with tri-tone transmissions, by which the staircase dual damascene profiles can be formed into a photoresist by one exposure.

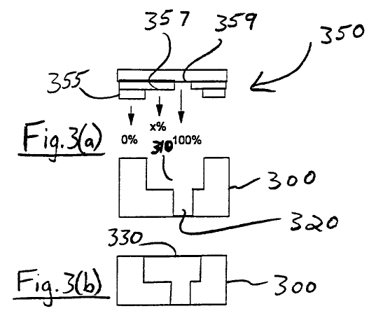

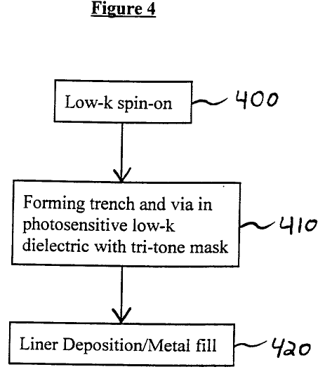

Referring now to the drawings, and more particularly to FIGS. 3(a) and 3(b), there are shown preferred embodiments of the method according to the present invention, whereby a new low-k/Cu dual damascene integration scheme is illustrated. The integration process sequences, further depicted in the flowchart in FIG. 4, are as follows: first, a spin-on process 400 is performed for a photosensitive low-k dielectric 300. Second, a trench (line) 310 and via 320 photos are formed 410 with a tri-tone mask 350 to form staircase structures in a photosensitive low-k dielectric 300. Third, a liner deposition/metal fill 330 is applied 420 into the trench. The tri-tone mask preferably has transmissions of 0% (or approximately 6% for attenuate PSM) for the non-erosion part 355 of the positive resist, x% (exact number can be given after simulation or experiment) for trenches 357 and 100% for vias 359.

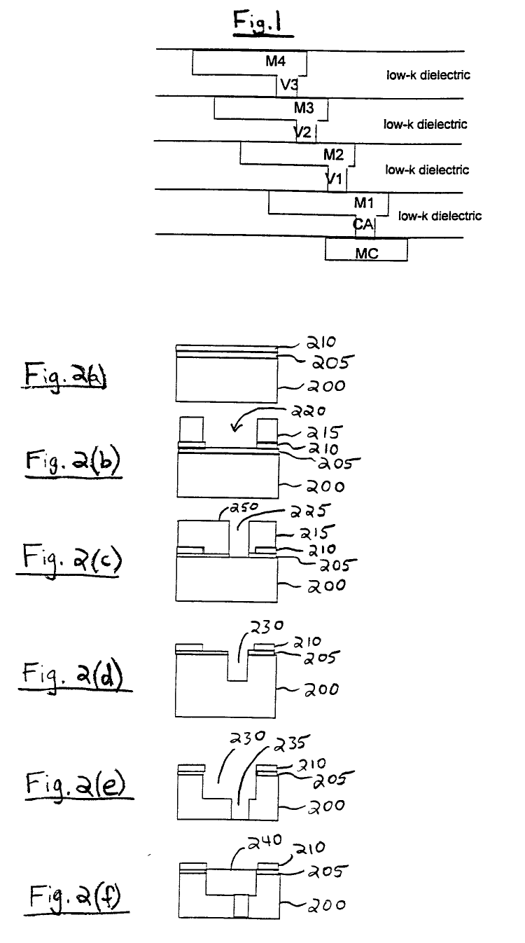

The present mask 350 is a non-contact mask. The disadvantage of contact printing is the defect problem previously indicated. The mechanical action of bringing a mask and a wafer into close contact creates debris which causes damage to both the mask and resist surface, and furthermore, introduces undesirable defects. These defects are reproduced in all subsequent exposures with consequent reduction in device yields. The problem and limitation of contact printing led to the development of projection printing, in which the mask and wafer are separated by several centimeters, and lens elements are used to focus the mask image onto the wafer surface. The projection printing techniques described herein, lowers the defect densities and concomitant net improvement in device yield, registration, and performance. These advantages account for the dominance of these techniques in ULSI production today. In FIGS. 1 through 3, the projection lenses are ignored.

A mask having a tri-tone density (opacity) can be fabricated by using two different materials. The different opacity regions are clear, semiopaque and opaque to the input radiation. A conventional chrome (Cr) mask blank can be used to fabricate the tri-tone density mask. An alternative material for the semitransparent layer is ion oxide. There are several ways to fabricate such a mask. One method is by first making a conventional chromeon a glass mask (opaque area formed on transparent glass). Second, the resist is coated and patterned, where the required transparent area is protected by the resist. Third, a thin film of SiO is deposited. Finally, the resist is lifted for the unwanted SiO area.

The basic steps of the lithographic process includes exposure and development. The resist material is applied as a thin coating over a base and is subsequently exposed, such that light strikes selected areas of the resist material. The exposed resist is then subjected to a development step, which generally involves immersion in an appropriate solvent. Depending on the chemical nature of the resist material, the exposed areas may be rendered more soluble in the developing solvent than the unexposed areas, thereby producing a positive tone image of the mask. The net effects of this process is to produce a three-dimensional relief image in the resist material that is a replication of the opaque and transparent area of the mask. However, the dissolution rate of the photoresist in the developer is a function of the exposure intensity. The resist area exposed by the semitransparent part of the mask is developed slower than the transparent area, hence stair case profiles are formed in the resist.

There are several key advantages of the present invention. The primary advantage of this invention is to reduce dual damascene processing costs by the combination of two lithography steps into one step. This simultaneously removes the etch problem. Another advantage is that the difficulty (previous level lithography formed topography) of a second level lithography will not exist. Another advantage is to improve the overlay accuracy between the building line and via. Conventionally, both the line and via align to the previous level. Thus, the overlay error of the building line and via is increased. With the present novel tri-tone mask, the placement errors between the line and via which forms the dual damascene structures are minimized since only one mask is used. Here, the overlay error between the line and via on the mask is very small due to the high performance of the mask writer (four times better) and the existing overlay error on the mask is further reduced in wafer reduction exposure.

As indicated above, in the tri-tone mask fabrication process, the semitransparent (to form wire) and transparent area (to form via) of the mask are patterned in separate e-beam or laser writing processes. Overlay error between the two areas can occur due to the registration limitation of the mask writing system as occurred in the wafer exposure system. However, the mask writers usually have a better registration accuracy than wafer exposure tools, thus the overlay error between the wire and via patterns on the mask is smaller. Furthermore, the wafer exposure tool is usually a reduction system from the mask to wafer image, so the overlay error is further reduced in the resist by the same demagnification.

Moreover, as previously mentioned, the traditional ways to form a dual damascene structure are to use two optical masks or an e-beam. Two masks are expensive and an e-beam is not efficient to shoot wafers in production. Therefore, using a tri-tone mask to form a dual damascene structure is both a cost saving and practical method for ULSI fabrication. Hence, in a preferred embodiment of the present invention, a process is disclosed to provide mid-transmission of the tri-tone mask and to make the reticle.

As previously mentioned, the goal of using a dual damascene process is to form staircase profiles in the dielectric film. The present invention performs this goal by focusing on the nature of the low-k material and photoresist. Again, most of the low-k dielectric candidates are organic spin-on material. Thus, it is feasible to make them photosensitive and then to use photolithography only to define dielectric patterns directly. Furthermore, the photoresist is comprised of organic spin-on material, which is photosensitive, wherein the exposed area (positive resist) or unexposed area (negative resist) are soluble in the developing solvents.

The net effect of the current photolithography process is to produce a three-dimensional relief image in the resist material that is a replication of the opaque and transparent areas on the mask. The resist can be divided into two categories depending on the basic nature of the design: 1) one-component systems are resists formed of pure polymers; that is, single substances that combine radiochemical reactivity; and 2) in two-component systems, the resist is formulated from two substances; that is, an inert matrix resin (which serves only as a binder and film-forming material), and a sensitizer molecule that, in general, is monomeric in nature and undergoes the radiochemical transformations that are responsible for imaging. The photosensitive low-k dielectric can be a two-component system formulated from a low-k dielectric and a sensitizer molecule.

The present invention is easily applicable for four, five, six, etc.-tone mask structures, and can be made in the similar way as the present tri-tone mask. These kinds of masks can be used to print stair case resist profiles as needed. The formed resist shape can act as molds to be filled (deposition or electroplating) with metals. Then, micrometal devices are produced with a corresponding productive and accurate printing technique. One application for the present invention involves micromachining, including sensors, actuators, microoptics and microrectors.

While the invention has been described in terms of preferred embodiments, those skilled in the art will recognize that the invention can be practiced with modification within the spirit and scope of the appended claims.

What is claimed is:

1. A method for forming interconnect dual damascene structures comprising:
performing a low-k dielectric spin-on; wherein said low-k dielectric is photosensitive;
forming trench and vias in said low-k dielectric with a tri-tone mask; and
applying a liner deposition in said trench and vias.

2. The method of claim 1, wherein said tri-tone mask comprises a plurality of transmission ratings.

3. The method of claim 2, wherein said transmissions of said tri-tone mask comprises a transmission rating of 0% corresponding to non-erosion regions of said dielectric.

4. The method of claim 2, wherein said transmissions of said tri-tone mask comprises a transmission rating of 100% corresponding to via regions of said dielectric.

5. The method of claim 2, wherein said transmission ratings of said tri-tone mask are in the range of 0% to 100%.

6. The method of claim 5, wherein said range between 0% and 100% corresponds to trench regions of said dielectric.

7. The method of claim 1, wherein said low-k dielectric comprises a photosensitive organic material.

8. A method for forming interconnect dual damascene structures comprising:
performing a low-k dielectric spin-on; wherein said low-k dielectric is photosensitive;
forming dual damascene structures in said low-k dielectric by exposing said low-k dielectric with a tri-tone mask once;
applying a liner deposition in said trench and vias; wherein said liner deposition comprises a thin film and prevents metal from diffusing into said low-k dielectric material; and
applying a metal fill in said trench and vias; wherein said metal fill comprises one of a metal deposition and electroplating.

9. The method of claim 8, wherein said tri-tone mask comprises a plurality of transmission ratings.

10. The method of claim 9, wherein said transmissions of said tri-tone mask comprises a transmission of 0% corresponding to non-erosion regions of said dielectric.

11. The method of claim 9, wherein said transmissions of said tri-tone mask comprises a transmission of 100% corresponding to via regions of said dielectric.

12. The method of claim 9, wherein said transmissions of said tri-tone mask is in the range of 0% to 100%.

13. The method of claim 12, wherein said range between 0% and 100% corresponds to trench regions of said dielectric.

14. The method of claim 8, wherein said low-k dielectric comprises photosensitive organic material.

15. A method of forming a step structure in a photo sensitive substrate comprising:
supplying said photosensitive substrate;
positioning a multi-tone mask above said substrate;
exposing said substrate through said mask;
developing said substrate;
rinsing said substrate to remove portions of said substrate and form said step structure.

16. The method in claim 15, wherein said multi-tone mask has regions of different optical densities.

17. The method in claim 15, wherein said different optical densities allow different amounts of light to pass such that regions of said substrate are subjected to different amounts of light exposure.

18. The method in claim 17, wherein said different amounts of light exposure allow the depth of the substrate removed by said rinsing to be selectively controlled.
